(19) United States
(12) Patent Application Publication
(10) Pub. No.: US 2023/0395597 A1
(43) Pub. Date: Dec. 7, 2023

(54) SEMICONDUCTOR DEVICE AND METHOD OF FORMING THE SAME

(71) Applicant: MICRON TECHNOLOGY, INC., BOISE, ID (US)

(72) Inventor: Takuya Imamoto, Higashihiroshima (JP)

(73) Assignee: MICRON TECHNOLOGY, INC., BOISE, ID (US)

(21) Appl. No.: 17/833,749

(22) Filed: Jun. 6, 2022

(51) Int. Cl. H01L 27/088; H01L 29/49; H01L 29/51; H01L 21/28; H01L 21/8234

(52) U.S. Cl. CPC H01L 27/088; H01L 29/4966; H01L 29/517; H01L 21/28088; H01L 21/82345; H01L 21/823481

(57) ABSTRACT

A semiconductor device includes a first transistor of a first conductivity type having a first gate insulating film and a first gate structure on the first gate insulating film, the first gate structure including a first conductive film, a second conductive film on the first conductive film and a third conductive film on the second conductive film; and a second transistor of the first conductivity type having a second gate insulating film and a second gate structure on the second gate insulating film, the second gate structure including a fourth conductive film and a fifth conductive film on the fourth conductive film; wherein the first gate insulating film and the second gate insulating film are the same, the second conductive film and the fourth conductive film are the same and the third conductive film and the fifth conductive film are the same.

### BACKGROUND

In metal-oxide-semiconductor field-effect transistors (hereinafter referred to as MOSFETs) included in a semiconductor device, the threshold voltages are controlled by introducing impurities into the channel regions below the gate electrodes. Impurities of a concentration corresponding to each threshold voltage are introduced into the channel regions.

When many impurities are introduced into a channel region to control the threshold voltage of a MOSFET, sub-threshold leakage current, gate-induced drain leakage (hereinafter referred to as GIDL), or junction leakage current may increase in the MOSFET in some cases.

### BRIEF DESCRIPTION OF THE DRAWINGS

FIG. 1 is a plan-view layout illustrating an example of a schematic configuration of a semiconductor device according to first and second embodiments.

FIG. 2 is a diagram illustrating one example of the schematic configuration of the semiconductor device according to the first embodiment. FIG. 2 is a longitudinal section illustrating an example of the schematic configuration of the portion along the line A-A in FIG. 1.

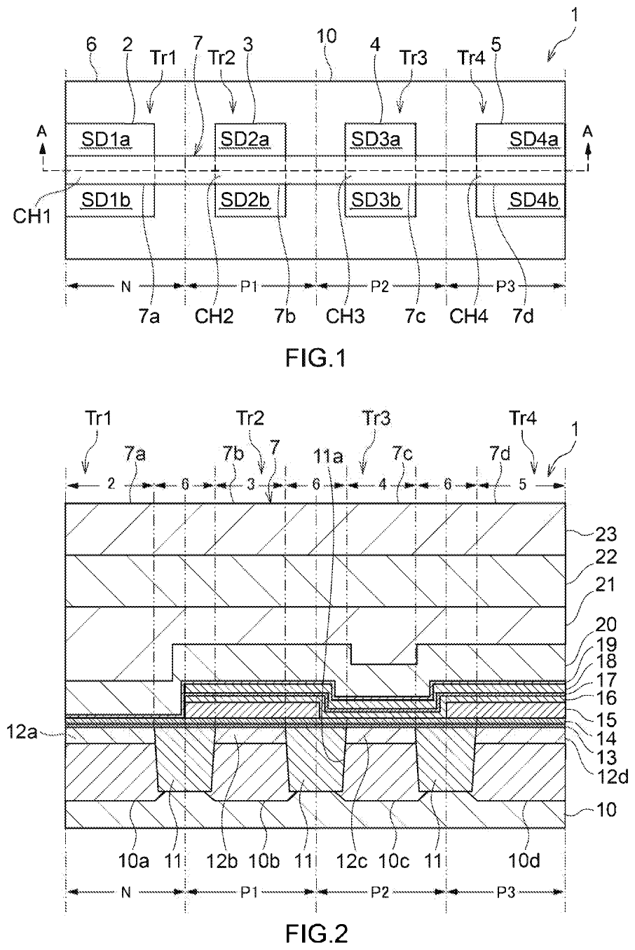

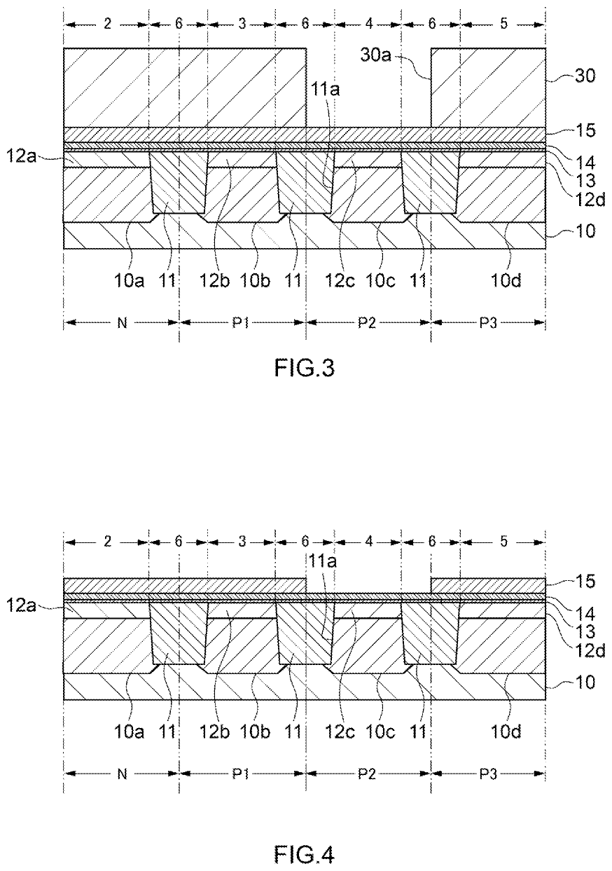

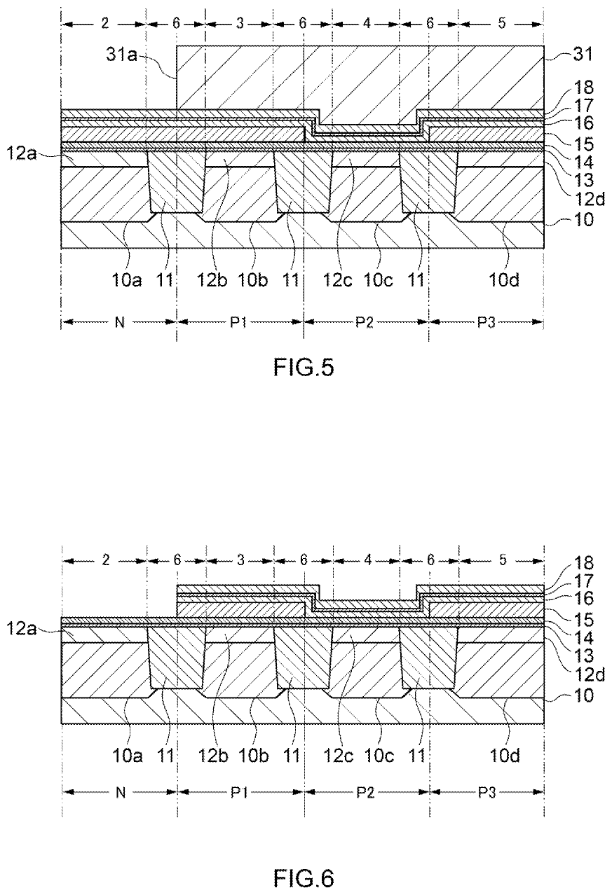

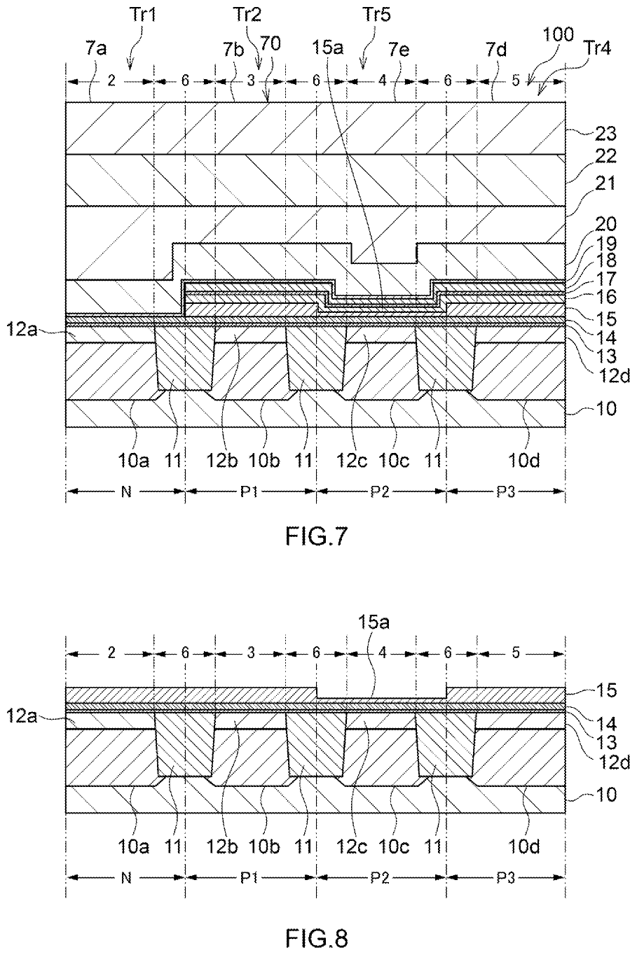

FIGS. 1 to 6 are diagrams illustrating a method of forming the semiconductor device according to the first embodiment. FIGS. 2 to 6 are diagrams that sequentially illustrate one example of the schematic configuration in exemplary process stages. FIGS. 2 to 6 are longitudinal sections illustrating the schematic configuration of the portion along the line A-A in FIG. 1.

FIG. 7 is a diagram illustrating one example of the schematic configuration of the semiconductor device according to the second embodiment. FIG. 7 is a longitudinal section illustrating an example of the schematic configuration of the portion along the line A-A in FIG. 1.

FIGS. 3, 7, and 8 are diagrams illustrating a method of forming the semiconductor device according to the second embodiment. FIGS. 3, 7, and 8 are diagrams that sequentially illustrate one example of the schematic configuration in exemplary process stages. FIGS. 7 and 8 are longitudinal sections illustrating the schematic configuration of the portion along the line A-A in FIG. 1.

### DETAILED DESCRIPTION

Various embodiments of the present disclosure will be explained below in detail with reference to the accompanying drawings. The following detailed description refers to the accompanying drawings that show, by way of illustration, specific aspects and various embodiments of the present disclosure. The detailed description provides sufficient detail to enable those skilled in the art to practice these embodiments of the present disclosure. Other embodiments may be utilized, and structure, logical and electrical changes may be made without departing from the scope of the present disclosure. The various embodiments disclosed herein are not necessary mutually exclusive, as some disclosed embodiments can be combined with one or more other disclosed embodiments to form new embodiments.

Hereinafter, a semiconductor device 1 and a method of forming the same according to a first embodiment will be described with reference to FIGS. 1 to 6. In the description of the embodiment, common or related elements and elements that are substantially the same are denoted with the same signs, and the description thereof will be reduced or omitted. In the drawings, the dimensions and dimensional ratios of each unit in each of the drawings do not necessarily match the actual dimensions and dimensional ratios in the embodiment. The vertical direction of each corresponding portion in the plan views and longitudinal sections refers to the direction in the case where the semiconductor substrate 10 is disposed at the bottom, and the horizontal direction refers to the direction parallel to the surface of the semiconductor substrate 10.

FIG. 1 is a plan view illustrating one example of a schematic configuration of a semiconductor device according to the first embodiment. The semiconductor device 1 according to the first embodiment is provided with a plurality of transistors. In FIG. 1, transistors Tr1 to Tr4 provided with different threshold voltages are illustrated as an example of the plurality of transistors provided in the semiconductor device 1. The transistor Tr1 includes an N-channel MOSFET. The transistors Tr2 to Tr4 include P-channel MOSFETs.

Also, each of the transistors Tr2 to Tr4 is set to have either a first threshold voltage Vt1 or a second threshold voltage Vt2 different from the first threshold voltage Vt1. In the following description, the first threshold voltage Vt1 is assumed to be a higher voltage value than the second threshold voltage Vt2. The transistors Tr2 and Tr4 have the first threshold voltage Vt1, while the transistor Tr3 has the second threshold voltage Vt2.

FIG. 1 illustrates four active regions 2 to 5 provided on a semiconductor substrate 10. The active regions 2 to 5 are demarcated from each other by being surrounded by an isolation region 6. On the upper surface of the semiconductor substrate 10, a gate electrode 7 is disposed to cut across the active regions 2 to 5. In the active region 2, a source-drain SD1a, SD1b is provided on either side of the gate electrode 7. Also, in the active region 2, a channel CH1 is provided underneath the gate electrode 7. Similarly, in the active region 3, a source-drain SD2a, SD2b and a channel CH2 are provided. Similarly, in the active region 4, a source-drain SD3a, SD3b and a channel CH3 are provided. Similarly, in the active region 5, a source-drain SD4a, SD4b and a channel CH4 are provided.

The gate electrode 7 is provided with gate electrode portions 7a to 7d that correspond to the transistors Tr1 to Tr4, respectively. The transistors Tr1 to Tr4 are respectively provided in formation regions N and P1 to P3 of the semiconductor substrate 10. The transistor Tr1 is provided with the source-drain SD1a, SD1b, the channel CH1, and the gate electrode portion 7a. The transistor Tr2 is provided with the source-drain SD2a, SD2b, the channel CH2, and the gate electrode portion 7b. The transistor Tr3 is provided with the source-drain SD3a, SD3b, the channel CH3, and the gate electrode portion 7c. The transistor Tr4 is provided with the source-drain SD4a, SD4b, the channel CH4, and the gate electrode portion 7d.

FIG. 2 is a diagram illustrating one example of the schematic configuration of the semiconductor device according to the first embodiment. FIG. 2 is a longitudinal section illustrating an example of the schematic configuration of the portion along the line A-A in FIG. 1. As illustrated in FIG. 2, an isolation insulating film 11 is provided in the isolation region 6 of the semiconductor substrate 10. The isolation insulating film 11 is embedded into isolation grooves 11a provided in the isolation region 6. The isolation insulating film 11 contains an insulating material such as silicon dioxide, for example.

A first well 10a to a fourth well 10d are provided in the semiconductor substrate 10. The first well 10a to the fourth well 10d are respectively provided in the active regions 2 to 5 of the semiconductor substrate 10. The first well 10a contains a prescribed concentration of a P-type impurity such as boron, for example. The second well 10b to the fourth well 10d contain prescribed concentrations of N-type impurities such as phosphorus or arsenic, for example. The N-type impurity concentrations of the second well 10b to the fourth well 10d may be the same or different.

A channel doping region 12a is provided in the channel CH1 of the active region 2. A channel doping region 12b is provided in the channel CH2 of the active region 3. A channel doping region 12c is provided in the channel CH3 of the active region 4. A channel doping region 12d is provided in the channel CH4 of the active region 5. The channel doping regions 12a to 12d have prescribed concentrations of channel doping impurities. P-type or N-type impurities such as phosphorus, arsenic, or boron are used as the channel doping impurities. The impurity concentration of each of the channel doping regions 12a to 12d is adjusted in accordance with the desired threshold voltage. A first insulating film 13 and a second insulating film 14 are layered onto the upper surface of the channel doping regions 12a to 12d. The first insulating film 13 and the second insulating film 14 function as gate insulating films for the transistors Tr1 to Tr4. The first insulating film 13 contains an insulating material such as silicon dioxide or silicon oxynitride, for example. The second insulating film 14 contains an insulating material such as hafnium oxide, for example. The second insulating film 14 includes a high-k film. A high-k film has a relative permittivity higher than at least silicon dioxide.

The gate electrode 7 is provided with the gate electrode portions 7a to 7d that respectively correspond to the transistors Tr1 to Tr4. The gate electrode portion 7b of the transistor Tr2 and the gate electrode portion 7d of the transistor Tr4 have a layered structure in which a first conductive film 15, a second conductive film 16, a third conductive film 17, a fourth conductive film 18, a fifth conductive film 19, a sixth conductive film 20, a seventh conductive film 21, an eighth conductive film 22, and a third insulating film 23 are layered in order from the bottom up. The gate electrode portion 7c of the transistor Tr3 has a layered structure in which the second conductive film 16, the third conductive film 17, the fourth conductive film 18, the fifth conductive film 19, the sixth conductive film 20, the seventh conductive film 21, the eighth conductive film 22, and the third insulating film 23 are layered in order from the bottom up. The gate electrode portion 7a of the transistor Tr1 has a layered structure in which the fifth conductive film 19, the sixth conductive film 20, the seventh conductive film 21, the eighth conductive film 22, and the third insulating film 23 are layered in order from the bottom up. The first embodiment illustrates an exemplary configuration in which the gate electrode portions 7a to 7d are disposed in correspondence with the transistors Tr1 to Tr4 as a portion of the gate electrode 7, but the configuration is not limited thereto. Another configuration is possible in which independent gate electrodes are provided for each of the transistors Tr1 to Tr4.

The first conductive film 15, second conductive film 16, fourth conductive film 18, and sixth conductive film 20 contain a conductor such as titanium nitride or a titanium aluminum nitride alloy, for example. The third conductive film 17 contains a conductor such as aluminum, for example. The fifth conductive film 19 contains a conductor such as lanthanum, for example.

In the above configuration, the gate electrode portions 7b and 7d include the first conductive film 15, whereas the gate electrode portion 7c does not include the first conductive film 15. For this reason, the thickness of the conductive film between the second insulating film 14 and the third conductive film 17, or in other words the thickness of the titanium nitride, is greater in the transistors Tr2 and Tr4 than in the transistor Tr3.

Next, FIGS. 2 to 6 will be referenced to describe a method of forming the semiconductor device 1 according to the first embodiment.

FIG. 3 will be referenced to describe a method of forming the semiconductor device 1 up to the configuration illustrated in the drawings. For the semiconductor substrate 10, a single-crystal silicon substrate can be used, for example. In the semiconductor substrate 10, the isolation grooves 11a are formed to a prescribed depth in the isolation region 6. In the formation of the isolation grooves 11a, known photolithography technology and anisotropic dry etching technology are used, for example.

Next, an insulating film is embedded into the isolation grooves 11a. The insulating film is formed by chemical vapor deposition (hereinafter referred to as CVD) or by an application method, for example. The insulating material contains silicon dioxide, for example. Next, chemical mechanical polishing (hereinafter referred to as CMP), for example, is performed on the insulating film to remove other portions while leaving the portions inside the isolation grooves 11a. With this arrangement, the isolation insulating film 11 is formed inside the isolation grooves 11a.

Next, in the semiconductor substrate 10, the wells 10a to 10d are formed in correspondence with the transistors Tr1 to Tr4. The wells 10a to 10d are formed by introducing impurities using known photolithography technology and ion implantation technology, for example, and then performing a heat treatment for impurity activation. Boron, for example, is introduced into the well 10a as a P-type impurity. Phosphorus or arsenic, for example, is introduced into the wells 10b to 10d as an N-type impurity. After the introduction of the impurities, a heat treatment at a temperature of approximately 1000° C., for example, is performed in a nitrogen atmosphere, for example.

Next, the first insulating film 13 and the second insulating film 14 are formed on the active regions 2 to 5 of the semiconductor substrate 10 and the isolation insulating film 11. The first insulating film 13 is formed by thermal oxidation or CVD, for example. The second insulating film 14 is formed by CVD, for example. Next, the first conductive film 15 is formed on the second insulating film 14. The first conductive film 15 is provided with titanium nitride, for example. The first conductive film 15 is formed by known sputtering technology or by atomic layer deposition (hereinafter referred to as ALD) technology, for example.

Next, a photoresist 30 provided with an opening 30a is formed in the formation region P2 by known photolithography technology. The upper surface of the first conductive film 15 is exposed in the opening 30a.

Next, known wet etching technology is performed using the photoresist 30 as a mask to etch the first conductive film 15 exposed in the opening 30a. In the wet etching, an etching solution such as ammonia hydrogen peroxide mixture (hereinafter referred to as APM) or hydrochloric hydrogen peroxide mixture (hereinafter referred to as HPM) is used, for example. Through the etching, the first conductive film 15 is removed and the upper surface of the second insulating film 14 is exposed in the opening 30a. Thereafter, the photoresist 30 is stripped. Through the above steps, the structure illustrated in FIG. 4 is formed.

Next, as illustrated in FIG. 5, a multilayer film including the second conductive film 16, the third conductive film 17, and the fourth conductive film 18 is formed. The second conductive film 16 and the fourth conductive film 18 contain a conductor such as titanium nitride or a titanium aluminum nitride alloy, for example. The third conductive film 17 contains a conductor such as aluminum, for example. The second conductive film 16, the third conductive film 17, and the fourth conductive film 18 are formed using ALD or plasma vapor deposition (hereinafter referred to as PVD) technology, for example. Through the above steps, a multilayer film including the second conductive film 16, the third conductive film 17, and the fourth conductive film 18 is formed on the first conductive film 15 in the formation regions N, P1, and P3. Also, in the formation region P2, a multilayer film including the second conductive film 16, the third conductive film 17, and the fourth conductive film 18 is formed on the second insulating film 14.

Next, a photoresist 31 provided with an opening 31a is formed in the formation region N by known photolithography technology. The upper surface of the fourth conductive film 18 is exposed in the opening 31a.

Next, the fourth conductive film 18, third conductive film 17, second conductive film 16, and first conductive film 15 exposed in the opening 31a are etched by known wet etching technology, for example, using the photoresist 31 as a mask. In the wet etching, an etching solution such as APM or HPM is used, for example. The etching removes the fourth conductive film 18, the third conductive film 17, the second conductive film 16, and the first conductive film 15 in the opening 31a and exposes the upper surface of the second insulating film 14. Thereafter, the photoresist 31 is stripped. Through the above steps, the structure illustrated in FIG. 6 is formed.

Thereafter, annealing is performed. The annealing is performed in a nitrogen atmosphere or a nitrogen atmosphere with oxygen at a temperature of approximately 1000° C., for example. The annealing causes the conductor (in the present embodiment, aluminum) in the third conductive film 17 to move by thermal diffusion. At this time, the aluminum in the third conductive film 17 is more concentrated between the first insulating film 13 and the second insulating film 14 compared to other portions. The amount of aluminum concentrated between the first insulating film 13 and the second insulating film 14 is controlled by adjusting the thickness of the conductive film(s) between the third conductive film 17 and the second insulating film 14, or in other words the thickness of the titanium nitride. The thinner the conductive film(s) between the third conductive film 17 and the second insulating film 14, or in other words the thinner the titanium nitride, the greater is the amount of aluminum concentrated between the first insulating film 13 and the second insulating film 14. Consequently, if gate electrodes with different thicknesses of the conductive film(s) between the third conductive film 17 and the second insulating film 14 are formed, gate electrodes with different amounts of aluminum concentrated between the first insulating film 13 and the second insulating film 14 can be formed.

In the formation regions P1 and P3 of the transistors Tr2 and Tr4, the first conductive film and the second conductive film 16 are provided between the third conductive film 17 and the second insulating film 14. In the formation region P2 of the transistor Tr3, the second conductive film 16 is provided between the third conductive film 17 and the second insulating film 14. Consequently, in the formation regions P1 and P3 of the transistors Tr2 and Tr4, the thickness of the conductive films between the third conductive film 17 and the second insulating film 14, or in other words the thickness of the titanium nitride, is greater than in the formation region P2 of the transistor Tr3. Consequently, the amount of aluminum concentrated between the first insulating film 13 and the second insulating film 14 in the formation region P2 is greater than the amount of aluminum concentrated between the first insulating film 13 and the second insulating film 14 in the formation regions P1 and P3.

Next, as illustrated in FIG. 2, the fifth conductive film 19, the sixth conductive film 20, the seventh conductive film 21, the eighth conductive film 22, and the third insulating film 23 are formed. The fifth conductive film 19 contains lanthanum, for example. The fifth conductive film 19 is formed by ALD or PVD, for example. The sixth conductive film 20 contains titanium nitride, for example. The sixth conductive film 20 is formed by sputtering or ALD, for example. The seventh conductive film 21 contains a conductor such as polycrystalline silicon, for example. The eighth conductive film 22 contains a conductor such as tungsten, for example. The third insulating film 23 contains an insulating material such as silicon nitride, for example. With this arrangement, in the formation region N, the fifth conductive film 19, the sixth conductive film 20, the seventh conductive film 21, the eighth conductive film 22, and the third insulating film 23 are formed on the second insulating film 14. In the formation regions P1 to P3, the fifth conductive film 19, the sixth conductive film 20, the seventh conductive film 21, the eighth conductive film 22, and the third insulating film 23 are formed on the fourth conductive film 18.

Thereafter, the third insulating film 23, eighth conductive film 22, seventh conductive film 21, sixth conductive film 20, fifth conductive film 19, fourth conductive film 18, third conductive film 17, second conductive film 16, and first conductive film 15 are etched by known photolithography technology and anisotropic dry etching technology, for example, and the gate electrode 7 having the planar shape illustrated in FIG. 1 is formed. With this arrangement, the gate electrode portions 7a to 7d provided in the gate electrode 7 are given the layered structure illustrated in FIG. 2.

Through the above steps, the semiconductor device 1 according to the first embodiment is formed.

According to the semiconductor device 1 and the method for forming the same according to the first embodiment, the following effects are obtained.

In the P-channel transistors Tr2 to Tr4, the gate electrode portions 7b and 7d are provided with a layered structure different from the gate electrode portion 7c. The gate electrode portion 7c is provided with the second conductive film 16 between the third conductive film 17 and the second insulating film 14. The gate electrode portions 7b and 7d are provided with the first conductive film 15 and the second conductive film 16 between the third conductive film 17 and the second insulating film 14. For this reason, in the gate electrode portion 7c, the amount of conductive material, namely aluminum, in the third conductive film 17 concentrated between the first insulating film 13 and the second insulating film 14 is greater than in the gate electrode portions 7b and 7c.

The threshold voltage of a MOSFET is controlled through adjustment of the effective work function of the gate electrode and through adjustment of the channel doping impurity concentration. In the case where adjustment of the effective work function of the gate electrode is used, the channel doping impurity concentration necessary to obtain a target threshold voltage can be lowered compared to the case where adjustment of the effective work function of the gate electrode is not used.

In the first embodiment, the greater the amount of aluminum concentrated between the first insulating film 13 and the second insulating film 14, the greater is the amount of change in the effective work function. In the first embodiment, the greater the amount of aluminum concentrated between the first insulating film 13 and the second insulating film 14, the more effective work function of the gate electrode is adjusted to achieve a lower threshold voltage of the MOSFET. With this arrangement, the first threshold voltage Vt1 of the transistor Tr3 is lower than the second threshold voltage Vt2 of the transistors Tr2 and Tr4.

As above, in the first embodiment, by forming gate electrodes with different thicknesses of the conductor, or in other words the titanium nitride, between the third conductive film 17 and the second insulating film 14, gate electrodes with different amounts of aluminum concentrated between the first insulating film 13 and the second insulating film 14 can be formed. With this arrangement, gate electrodes with different effective work functions can be formed, thereby making it possible to form MOSFETs with different threshold voltages.

Additionally, in the first embodiment, by adjusting the thickness of the conductor, or in other words the titanium nitride, between the third conductive film 17 and the second insulating film 14, the amount of aluminum concentrated between the first insulating film 13 and the second insulating film 14 can be adjusted. By adjusting the amount of aluminum concentrated between the first insulating film 13 and the second insulating film 14, the effective work function of the gate electrode of the MOSFET can be adjusted, thereby making it possible to control the threshold voltage of the MOSFET. With this arrangement, the concentration of the impurities introduced into the channel doping regions 12b to 12d for controlling the threshold voltage can be lowered. Moreover, in the case of introducing impurities of the opposite conductivity type of the well to lower the threshold voltage, or in other words, in the case of counter doping, the doping with such impurities can be eliminated or the impurities used for the doping can be reduced in quantity. With this arrangement, increases in the sub-threshold leakage current, GIDL, and junction leakage current in the transistors Tr2 to Tr4 can be suppressed.

Next, a semiconductor device 100 and a method of forming the same according to a second embodiment will be described with reference to FIGS. 1, 3, 7, and 8. Hereinafter, portions of the semiconductor device 100 that are the same as the first embodiment will be omitted, and the different portions will be described.

FIG. 7 is a diagram illustrating one example of the schematic configuration of the semiconductor device 100 according to the second embodiment. FIG. 7 is a longitudinal section illustrating the schematic configuration of the portion along the line A-A in FIG. 1. As illustrated in FIG. 7, in the second embodiment, the semiconductor device 100 is provided with a transistor Tr5 in the formation region P2 instead of the transistor Tr3 in the first embodiment. The semiconductor device 100 is provided with a gate electrode 70 instead of the gate electrode 7 in the first embodiment.

The gate electrode 70 is provided with a gate electrode portion 7e that corresponds to the transistor Tr5. The gate electrode portion 7e has a layered structure in which a ninth conductive film 15a, the second conductive film 16, the third conductive film 17, the fourth conductive film 18, the fifth conductive film 19, the sixth conductive film 20, the seventh conductive film 21, the eighth conductive film 22, and the third insulating film 23 are layered in order from the bottom up. The ninth conductive film 15a is provided with the same conductor as the first conductive film 15 and is thinner than the first conductive film 15.

Next, FIGS. 2, 8, and 7 will be referenced to describe a method of forming the semiconductor device 100 according to the second embodiment. As illustrated in FIG. 3, the photoresist 30 having the opening 30a is formed in the formation region P2 using known lithography technology. The upper surface of the first conductive film 15 is exposed in the opening 30a.

Next, as illustrated in FIG. 8, known wet etching technology is performed using the photoresist 30 as a mask, and etching is performed to leave behind a portion of the first conductive film 15 exposed in the opening 30a. The portion left behind by the etching is the ninth conductive film 15a. In the wet etching, an etching solution such as APM or HPM is used, for example. The thickness of the ninth conductive film 15a is controlled by adjusting the concentration of the etching solution or the etching time. Thereafter, the photoresist 30 is stripped. Through the above steps, the structure illustrated in FIG. 8 is formed. Thereafter, the structure illustrated in FIG. 7 is formed by performing steps similar to the manufacturing process in the first embodiment.

According to the semiconductor device 100 according to the second embodiment, effects similar to the semiconductor device 1 according to the first embodiment can be obtained. Also, according to the second embodiment, the semiconductor device 100 provided with the ninth conductive film 15a that is thinner than the first conductive film 15 in the gate electrode portion 7e can be formed. The thickness of the conductor (titanium nitride) between the third conductive film 17 and the second insulating film 14 in the gate electrode portion 7e is smaller than in the gate electrode portions 7b and 7d, and greater than in the gate electrode portion 7c in the first embodiment. Consequently, the amount of aluminum concentrated between the first insulating film 13 and the second insulating film 14 in the gate electrode portion 7e can be adjusted to be greater than in the gate electrode portions 7b and 7d, and less than the amount of aluminum concentrated between the first insulating film 13 and the second insulating film 14 in the gate electrode portion 7c in the first embodiment.

As above, by adjusting the thickness of the ninth conductive film 15a to be left behind in the step illustrated in FIG. 3, the effective work function of the gate electrode of the MOSFET can be adjusted. Consequently, the threshold voltage of the MOSFET can be controlled. According to the semiconductor device 100 according to the second embodiment, the transistor Tr5 can be adjusted to have a third threshold voltage Vt3. The third threshold voltage Vt3 is lower than the first threshold voltage Vt1 and higher than the second threshold voltage Vt2 of the first embodiment. Moreover, by adjusting the etching conditions to control the thickness of the ninth conductive film 15a, the third threshold voltage Vt3 can be controlled to a desired value.

The above describes the semiconductor devices 1 and 100 according to the first and second embodiments by taking the example of a configuration including P-channel MOSFETs provided with a plurality of threshold voltages, but the configuration is not limited thereto. The embodiments may also be applied to a semiconductor device including N-channel MOSFETs provided with a plurality of threshold voltages. Furthermore, the embodiments may also be applied to a semiconductor device provided with either P-channel transistors or N-channel transistors.

As above, methods of forming the semiconductor devices 1 and 100 according to the first and second embodiments are described by taking the example of an annealing step performed before the formation of the fifth conductive film 19 of the gate electrode 7, but the annealing may also be performed after the formation of the fifth conductive film 19. For example, the annealing may also be performed after the formation of the seventh conductive film 21.

Although various embodiments have been disclosed in the context of certain preferred embodiments and examples, it will be understood by those skilled in the art that the scope of the present disclosure extends beyond the specifically disclosed embodiments to other alternative embodiments and/or uses of the embodiments and obvious modifications and equivalents thereof. In addition, other modifications which are within the scope of this disclosure will be readily apparent to those of skill in the art based on this disclosure. It is also contemplated that various combination or sub-combination of the specific features and aspects of the embodiments may be made and still fall within the scope of the disclosure. It should be understood that various features and aspects of the disclosed embodiments can be combined with or substituted for one another in order to form varying modes of the disclosed embodiments. Thus, it is intended that the scope of at least some of the present disclosure should not be limited by the particular disclosed embodiments described above.

1. An apparatus comprising:
a first transistor of a first conductivity type having a first gate insulating film and a first gate structure on the first gate insulating film, the first gate structure including a first conductive film on the first gate insulating film, a second conductive film on the first conductive film and a third conductive film on the second conductive film; and
a second transistor of the first conductivity type having a second gate insulating film and a second gate structure on the second gate insulating film, the second gate structure including a fourth conductive film on the second gate insulating film and a fifth conductive film on the fourth conductive film;
wherein the first gate insulating film and the second gate insulating film are the same as each other;
wherein the second conductive film and the fourth conductive film are the same as each other; and
wherein the third conductive film and the fifth conductive film are the same as each other.

2. The apparatus of claim 1, wherein each of the first transistor and the second transistor has a planar-type structure.

3. The apparatus of claim 1, wherein the first transistor has a first threshold voltage, and the second transistor has a second threshold voltage different from the first threshold voltage.

4. The apparatus of claim 1, wherein the third conductive film includes a material that adjusts the effective work function of the first gate structure, and the fifth conductive film includes a material that adjusts the effective work function of the second gate structure.

5. The apparatus of claim 1, wherein each of the third conductive film and the fifth conductive film includes aluminum.

6. The apparatus of claim 1, wherein each of the first gate insulating film and the second gate insulating film includes a High-K insulating material.

7. The apparatus of claim 1, wherein each of the first gate insulating film and the second gate insulating film includes hafnium oxide.

8. An apparatus comprising:
a first transistor of a first conductivity type having a first gate insulating film, a second gate insulating film on the first gate insulating film and a first gate structure on the second gate insulating film, the first gate structure including a first conductive film on the first gate insulating film, a second conductive film on the first conductive film, a third conductive film on the second conductive film and a fourth conductive film on the third conductive film; and
a second transistor of the first conductivity type having a third gate insulating film, a fourth gate insulating film on the second gate insulating film and a second gate structure on the fourth gate insulating film, the second gate structure including a fifth conductive film on the second gate insulating film, a sixth conductive film on the fifth conductive film, a seventh conductive film on the sixth conductive film and an eighth conductive film on the seventh conductive film;
wherein the first gate insulating film and the third gate insulating film are the same as each other;
wherein the second gate insulating film and the fourth gate insulating film are the same as each other;
wherein the first conductive film and the fifth conductive film include a same material as each other;
wherein the second conductive film and the sixth conductive film are the same as each other;
wherein the third conductive film and the seventh conductive film are the same as each other;
wherein the fourth conductive film and the eighth conductive film are the same as each other; and
wherein the fifth conductive film is thinner than the first conductive film.

9. The apparatus of claim 8, wherein each of the first transistor and the second transistor has a planar-type structure.

10. The apparatus of claim 8, wherein the first transistor has a first threshold voltage, and the second transistor has a second threshold voltage different from the first threshold voltage.

11. The apparatus of claim 8, wherein the third conductive film includes a material that adjusts the effective work function of the first gate structure, and the seventh conductive film includes a material that adjusts the effective work function of the second gate structure.

12. The apparatus of claim 8, wherein each of the third conductive film and the seventh conductive film includes aluminum.

13. The apparatus of claim 8, wherein the second gate insulating film and the fourth gate insulating film includes hafnium oxide.

14. A method comprising:
forming an isolation region surrounding each of a plurality of active regions on a semiconductor substrate;
forming a first insulating film;
forming a second insulating film on the first insulating film;
depositing a first conductive film on the second insulating film;
etching the first conductive film in at least one of the plurality of active regions and exposing a portion of the second insulating film;
depositing a second conductive film, a third conductive film, and a fourth conductive film in this order; and
annealing so as to diffuse a part of a material included in the third conductive film between the first insulating film and the second insulating film.

15. The method of claim 14, wherein in the etching of the first conductive film, the first conductive film is removed and a surface of the second insulating film is exposed.

16. The method of claim 14, wherein in the etching of the first conductive film, a part of the first conductive film is removed to reduce the film thickness thereof.

17. The method of claim 14, wherein in the annealing, the material diffused between the first insulating film and the second insulating film adjusts the effective work function of a conductor on the second insulating film.

18. The method of claim 14, wherein the material included in the third film comprises aluminum.

19. The method of claim 14, wherein the second insulating film comprises hafnium oxide.

20. The method of claim 14, wherein the first conductive film and the second conductive film comprise titanium nitride.
